(19) United States
(12) Patent Application Publication
(10) Pub. No.: US 2025/0318071 A1
(43) Pub. Date: Oct. 9, 2025

(54) FAN MECHANISMS FOR HEAT MANAGEMENT IN ELECTRONICS AND RELATED METHODS

(71) Applicant: PLUME DESIGN, INC., Palo Alto, CA (US)

(72) Inventors: Ming-Tsung SU, Taipei City (TW); Wang-Chun WEN, Taoyuan City (TW); Richard CHANG, Los Altos Hills, CA (US)

(21) Appl. No.: 18/628,076

(22) Filed: Apr. 5, 2024

(51) Int. Cl. H05K 7/20

(52) U.S. Cl. CPC H05K 7/20209; H05K 7/20136

(57) ABSTRACT

Electronic devices may include at least one electronic component that generates heat during operation and a fan mechanism positioned and configured to induce flow of air to dissipate the heat generated by the at least one electronic component. A controller may be operably connected to the fan mechanism and programmed to intermittently operate the fan mechanism to repeatedly alternate between running the fan mechanism during a first predetermined time period and the fan mechanism being off during a second predetermined time period. Various other devices and methods are related to such electronic devices.

### BRIEF DESCRIPTION OF THE DRAWINGS

FIG. 1 is a bottom perspective view of an electronic device including a fan mechanism, according to at least one embodiment of the present disclosure.

FIG. 2 is a plot showing example temperatures of electronic components over time during intermittent operation of a fan mechanism, according to at least one embodiment of the present disclosure.

FIG. 3 is a chart showing example sound levels of a fan mechanism at various rotational speeds, according to at least one embodiment of the present disclosure.

FIG. 4 is a flow diagram illustrating a method of forming an electronic device including a fan mechanism, according to at least one embodiment of the present disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

In electronic devices, heat is generated by electronic components during operation. If the temperature of the electronic device rises too high, some electronic components may fail or operate poorly. In addition, a hot exterior may make it uncomfortable or dangerous to touch the electronic device.

These problems may especially affect compact electronic devices, such as wireless signal extenders, due to their small volume and limited space for passive cooling (e.g., due to ambient convection and/or radiation). Accordingly, compact electronic devices may include a fan and/or heat dissipation elements (e.g., heat sink fins) to remove heat from the electronic devices. Typically, cooling fans are continuously operated to provide maximum heat removal. For power management, fans may be operated at different speeds, such as at a high speed when temperatures are high and at a low speed when temperatures drop. Higher fan speeds typically result in increased fan noise. Higher fan speeds also may have a tendency to draw in additional dust into the electronics, which can block airflow, and therefore inhibit cooling, and which can potentially cause damage to electronic components.

The present disclosure provides detailed descriptions of electronic devices with fan mechanisms for heat management, and related methods. As will be explained in greater detail below, embodiments of the present disclosure may include an electronic device including at least one electronic component that generates heat during operation and a fan mechanism positioned and configured to induce flow of air to dissipate the heat generated by the electronic component(s). A controller may be operably connected to the fan mechanism and programmed to intermittently operate the fan mechanism to repeatedly alternate between running the fan mechanism during a first predetermined time period and the fan mechanism being off during a second predetermined time period. In some examples, such electronic devices may exhibit high fan life, low noise, low power, and/or low dust infiltration while still sufficiently cooling the electronic component(s) to inhibit heat damage.

Features from any of the embodiments described herein may be used in combination with one another in accordance with the general principles described herein. These and other embodiments, features, and advantages will be more fully understood upon reading the following detailed description in conjunction with the accompanying drawings and claims.

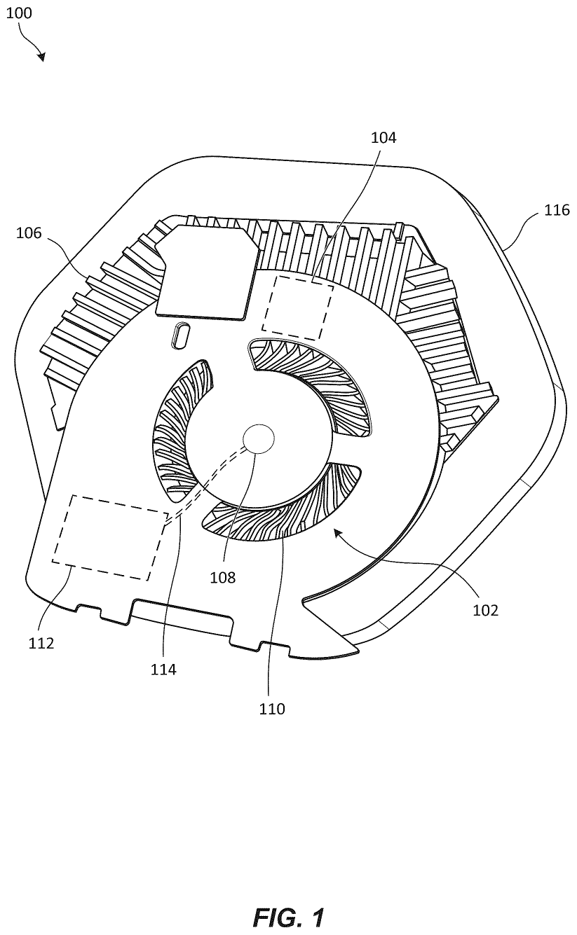

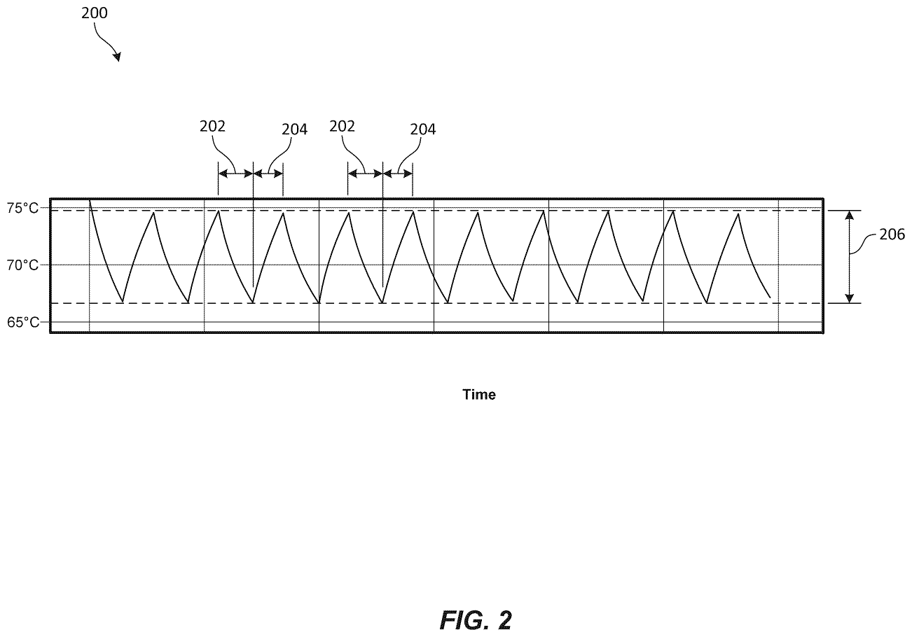

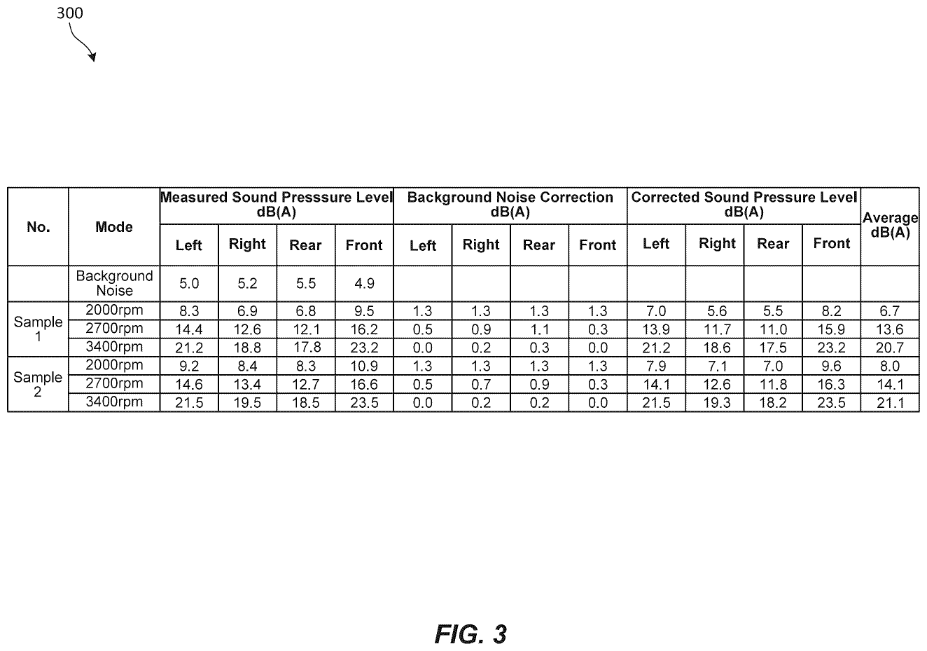

The following will provide, with reference to FIG. 1, a detailed description of an electronic device according to example embodiments of the present disclosure. With reference to FIGS. 2 and 3, the following will provide detailed descriptions of operating temperatures and noise levels, respectively, of electronic devices according to the present disclosure. Next, an example method of forming an electronic device of the present disclosure will then be described.

FIG. 1 is a bottom perspective view of an electronic device 100 including a fan mechanism 102, according to at least one embodiment of the present disclosure. The electronic device 100 may include at least one electronic component 104 that generates heat during operation. By way of example and not limitation, the electronic component(s) 104 may include a central processing unit (CPU), an embedded multimedia card (eMMC), a memory device, a wireless transceiver (e.g., configured to receive a wireless signal and transmit a wireless signal, such as an amplified wireless signal), a power supply, and/or an amplifier. Sub-elements of the electronic component(s) 104 (e.g., transistors, traces, resistors, capacitors, diodes, etc.) may exhibit at least some electrical resistance that causes the heat generation during operation (e.g., when electrical current is flowing therethrough).

The fan mechanism 102 may be positioned and configured to dissipate heat generated by the electronic component(s) 104 by inducing flow of air across the electronic component(s) 104 and/or across heat dissipation fins 106 adjacent to the fan mechanism 102 and/or adjacent to the electronic component(s) 104 that generate heat. The fan mechanism 102 may include a fan motor 108 and fan blades 110. A controller 112 may be operably connected (e.g., via a wired connection 114) to the fan mechanism 102 such that the controller 112 controls operation of the fan mechanism 102.

The controller 112 may be programmed to intermittently operate the fan mechanism 102 to repeatedly alternate the fan mechanism 102 between running the fan mechanism 102 during a first predetermined time period and the fan mechanism 102 being off (e.g., with the fan blades 110 stopped) during a second predetermined time period. The first predetermined time period and the second predetermined time period may be a same length or different lengths of time depending on the cooling needs of the electronic device 100. For example, the fan mechanism 102 may be run during the first predetermined time period of between four minutes and five minutes (e.g., four minutes and thirty seconds) and may be off during the second predetermined time period of between three minutes thirty seconds and four minutes thirty seconds (e.g., four minutes). Of course, if the electronic device 100 generates more heat, the first predetermined time period may be lengthened and/or the second predetermined time period may be shortened. Conversely, if the electronic device 100 generates less heat, the first predetermined time period may be shortened and/or the second predetermined time period may be lengthened. Environmental factors (e.g., ambient temperature, ambient airflow, humidity, etc.) may also affect the lengths of time of operating the fan mechanism 102 for effective cooling.

The electronic device 100 may also include a housing 116, which may contain the electronic component(s) 104 and the fan mechanism 102. In some embodiments, the electronic device 100 may be considered a small electronic device 100, with the housing 116 having an overall size of less than five inches (12.7 cm) cubed (e.g., fitting within a five-inch (12.7 cm) cube). In some examples, the housing 116 may have an overall size of less than four inches (10.16 cm) cubed, such as less than four inches (10.16 cm) by four inches (10.16 cm) by two inches (5.08 cm). In some non-limiting examples, the electronic device 100 may be a wireless communication device, such as a wireless signal extender.

Compared to continuous operation of the fan mechanism 102, operating the fan mechanism 102 between alternating periods of running and not running may result in reduced power consumption of the fan mechanism 102 and reduced overall noise generated by the fan mechanism 102, while still effectively managing the heat generated by the electrical component(s) 104. In addition, a life of the fan mechanism 102 may be extended (e.g., compared to continuous operation) due to the intermittent operation. Also, less dust may be pulled into the electronic device 100, improving performance of and reducing potential damage to the electronic component(s) 104.

FIG. 2 is a plot 200 showing example temperatures of an electronic component (e.g., the electronic component(s) 104 of FIG. 1, such as a CPU) over time during intermittent operation of a fan mechanism (e.g., the fan mechanism 102 of FIG. 1), according to at least one embodiment of the present disclosure. The plot 200 shows temperatures recorded at a CPU. A fan mechanism was intermittently operated by a controller (e.g., the controller 112 of FIG. 1) to run for first predetermined time periods 202 of about four minutes and thirty seconds each and be off for second predetermined time periods 204 of about four minutes each.

During the first predetermined time periods 202 when the fan mechanism was running, the temperature of the CPU dropped from close to 75° C. to about 67° C. During the second predetermined time periods 204 when the fan mechanism was off, the temperature of the CPU rose from about 67° C. to close to 75° C. The maximum temperatures of the CPU were within operational parameters for proper functioning and avoiding heat damage.

This intermittent operation of the fan mechanism may result in the CPU (or other electronic component(s)) being maintained within a predetermined temperature range 206. For example, the predetermined temperature range 206 may exhibit a maximum temperature difference between high and low temperatures of about 10° C. or less, such as about 8° C. or less. In the example shown in FIG. 2, the recorded low temperatures of the CPU were about 67° C. and the recorded high temperatures were about 75° C. Accordingly, the predetermined temperature range 206 in the example of FIG. 2 exhibited a maximum temperature difference of about 8° C. or less.

The plot 200 of FIG. 2 is provided as one example for a particular electronic device. Other electronic devices having different configurations, sizes, shapes, electronic components, fan sizes, etc., may include a fan mechanism that may be operated at different timer intervals to achieve acceptable cooling. In some embodiments, the controller may be programmed to adjust the time intervals of fan operation, such as based on a manual input and/or based on temperature feedback obtained from one or more temperature sensors in the electronic device.

In some examples, the electronic device of the present disclosure may be configured to intermittently operate a fan mechanism such that a temperature of a CPU of the electronic device may be maintained at less than 80° C., such as less than 75° C.

FIG. 3 is a chart 300 showing example sound levels of a fan mechanism at various rotational speeds, according to at least one embodiment of the present disclosure. In some examples, a controller (e.g., the controller 112 of FIG. 1) may be capable of causing a fan mechanism (e.g., the fan mechanism 102 of FIG. 1) to operate at a variety of rotational speeds. In the example used to create the chart 300, sound levels were measured using two samples and at three different fan speeds for each sample. The fan speeds were 2000 rpm, 2700 rpm, and 3400 rpm. Operating sound levels and background noise were measured, and the background noise was deducted from the measured levels to determine a corrected sound level at each fan speed. Averages of the corrected sound level were also determined and recorded.

As can be seen in the chart 300, lower fan speeds resulted in corresponding lower sound levels.

Accordingly, in some examples, the present disclosure may include operating a fan mechanism (e.g., the fan mechanism 102 of FIG. 1) at reduced rotational speeds to reduce sound levels generated by an electronic device (e.g., the electronic device 100 of FIG. 1). For example, during time periods of operating a fan mechanism (e.g., during the first predetermined time periods discussed above), a controller (e.g., the controller 112 of FIG. 1) may be programmed to operate the fan mechanism at rotational speeds of less than 2500 rpm, such as at about 2000 rpm or less. In some examples, the controller may operate the fan mechanism to generate less than 12 decibels of sound, such as less than 10 decibels of sound (e.g., at corrected sound levels with ambient noise deducted).

Although airflow may be lower when operating the fan mechanism at a lower rotational speed, the airflow may be sufficient to push heated air out of and/or away from the device and to replace the heated air with cooler ambient air. This airflow may result in maintaining the temperature of electronic components (e.g., the electronic component(s) 104 of FIG. 1) at appropriate levels to inhibit (e.g., reduce or eliminate) damage while keeping sounds low (e.g., at less than 12 decibels, less than 10 decibels, etc.).

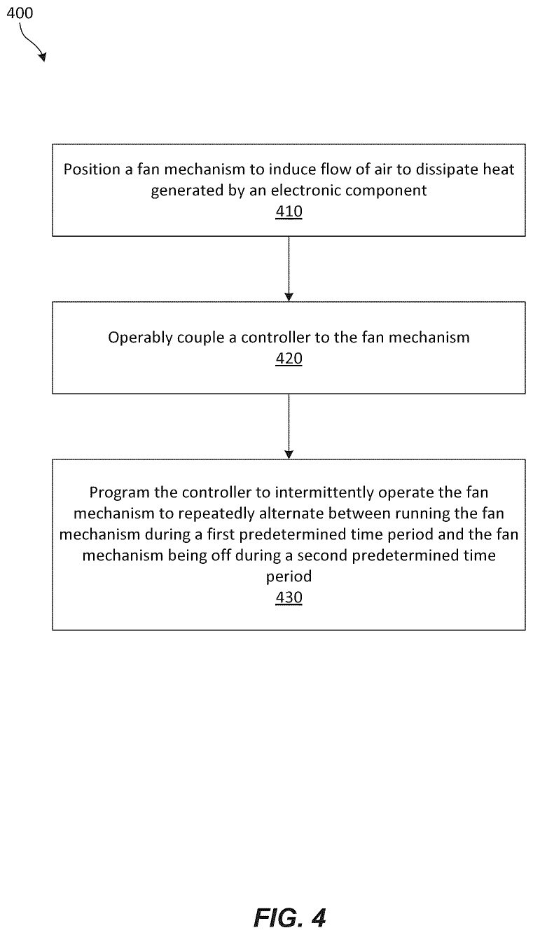

FIG. 4 is a flow diagram illustrating a method 400 of forming an electronic device including a fan mechanism, according to at least one embodiment of the present disclosure. At operation 410, a fan mechanism may be positioned in the electronic device to induce flow of air to dissipate heat generated by one or more electronic components of the electronic device.

At operation 420, a controller (e.g., a microcontroller, a CPU, etc.) may be operably coupled to the fan mechanism to be capable of controlling operation of the fan mechanism. For example, the controller may be coupled to the fan mechanism to control the on or off status of the fan mechanism and/or the rotational speed of the fan mechanism.

At operation 430, the controller may be programmed to intermittently operate the fan mechanism to repeatedly alternate between running the fan mechanism during a first predetermined time period and the fan mechanism being off during a second predetermined time period. For example, the intermittent operation of the fan mechanism may maintain a temperature of a central processing unit of the electronic device at less than 80° C. (e.g., less than 75° C.). In some examples, the controller may be programmed to run the fan mechanism at a rotational speed of 2500 rpm or less during the first predetermined time period.

In some examples, the term “about” in reference to a given parameter, property, or condition, may refer to a degree that one skilled in the art would understand that the given parameter, property, or condition is met with a small degree of variance, such as within acceptable manufacturing tolerances and/or conventional measurement techniques. For example, a parameter that is “about” met may be at least 90% met, at least 95% met, at least 99% met, or fully met.

In some examples, relational terms, such as “first,” “second,” etc., may be used for clarity and convenience in understanding the disclosure and accompanying drawings and do not connote or depend on any specific preference, orientation, or order, except where the context clearly indicates otherwise.

Accordingly, the present disclosure includes electronic devices (e.g., small electronic devices) with cooling fan mechanisms that can be operated intermittently to reduce power consumption, wear, and noise, while still providing sufficient cooling to inhibit damage to electronic components thereof.

The following example embodiments are also included in the present disclosure.

Example 1. An electronic device, including: at least one electronic component that generates heat during operation; a fan mechanism positioned and configured to induce flow of air to dissipate the heat generated by the at least one electronic component; and a controller operably connected to the fan mechanism and programmed to intermittently operate the fan mechanism to repeatedly alternate between running the fan mechanism during a first predetermined time period and the fan mechanism being off during a second predetermined time period.

Example 2. The electronic device of Example 1, wherein the first predetermined time period has a different length of time relative to the second predetermined time period.

Example 3. The electronic device of Example 1 or Example 2, wherein the first predetermined time period is greater than the second predetermined time period.

Example 4. The electronic device of any one of Examples 1 through 3, wherein the first predetermined time period is between four and five minutes and the second predetermined time period is between three minutes and thirty seconds and four minutes and thirty seconds.

Example 5. The electronic device of any one of Examples 1 through 4, wherein the first predetermined time period is about four minutes and thirty seconds and the second predetermined time period is about four minutes.

Example 6. The electronic device of any one of Examples 1 through 5, further including heat dissipation fins adjacent to the fan mechanism.

Example 7. The electronic device of any one of Examples 1 through 6, wherein the at least one electronic component includes at least one of: a central processing unit; an embedded multimedia card; a memory device; a wireless transceiver; a power supply; or an amplifier.

Example 8. The electronic device of any one of Examples 1 through 7, wherein the at least one electronic component includes electronic components of a wireless signal extender.

Example 9. The electronic device of any one of Examples 1 through 8, further including a housing containing the at least one electronic component and the fan mechanism, wherein the housing has an overall size of less than five inches cubed.

Example 10. The electronic device of Example 9, wherein the housing has an overall size of less than four inches cubed.

Example 11. The electronic device of any one of Examples 1 through 10, wherein the controller is programmed to run the fan mechanism during the first predetermined time period at a speed of less than 2500 rpm.

Example 12. The electronic device of any one of Examples 1 through 11, wherein the controller is programmed to run the fan mechanism during the first predetermined time period at a speed of about 2000 rpm or less.

Example 13. An electronic device, including: a central processing unit that generates heat during operation; a wireless transceiver operably coupled to and controlled by the central processing unit; a fan mechanism positioned and configured to induce flow of air to dissipate the heat generated by the central processing unit; and a controller operably connected to the fan mechanism and programmed to intermittently operate the fan mechanism to repeatedly alternate between running the fan mechanism during a first predetermined time period and the fan mechanism being off during a second predetermined time period to maintain a temperature of the central processing unit at less than 80° C.

Example 14. The electronic device of Example 13, wherein the intermittent operation of the fan mechanism maintains the temperature of the central processing unit at less than 75° C.

Example 15. The electronic device of Example 13 or Example 14, wherein the controller is configured to operate the fan mechanism at a speed of less than 2500 rpm during the first predetermined time period.

Example 16. The electronic device of any one of Examples 13 through 15, wherein the controller is configured to operate the fan mechanism to generate less than 12 decibels of sound when operating during the first predetermined time period.

Example 17. The electronic device of any one of Examples 13 through 16, wherein the wireless transceiver is configured to receive a wireless signal and transmit an amplified wireless signal.

Example 18. A method of forming an electronic device, the method including: positioning a fan mechanism to induce flow of air to dissipate heat generated by an electronic component; operably coupling a controller to the fan mechanism; and programming the controller to intermittently operate the fan mechanism to repeatedly alternate between running the fan mechanism during a first predetermined time period and the fan mechanism being off during a second predetermined time period.

Example 19. The method of Example 18, wherein the electronic device includes a central processing unit and the intermittent operation of the fan mechanism maintains a temperature of the central processing unit at less than 80° C.

Example 20. The method of Example 18 or Example 19, further including programming the controller to run the fan mechanism at less than 2500 rpm during the first predetermined time period.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An electronic device, comprising:
at least one electronic component that generates heat during operation;
a fan mechanism positioned and configured to induce flow of air to dissipate the heat generated by the at least one electronic component; and
a controller operably connected to the fan mechanism and programmed to intermittently operate the fan mechanism to repeatedly alternate between running the fan mechanism during a first predetermined time period and the fan mechanism being off during a second predetermined time period.

2. The electronic device of claim 1, wherein the first predetermined time period has a different length of time relative to the second predetermined time period.

3. The electronic device of claim 1, wherein the first predetermined time period is greater than the second predetermined time period.

4. The electronic device of claim 1, wherein the first predetermined time period is between four and five minutes and the second predetermined time period is between three minutes and thirty seconds and four minutes and thirty seconds.

5. The electronic device of claim 1, wherein the first predetermined time period is about four minutes and thirty seconds and the second predetermined time period is about four minutes.

6. The electronic device of claim 1, further comprising heat dissipation fins adjacent to the fan mechanism.

7. The electronic device of claim 1, wherein the at least one electronic component comprises at least one of:
a central processing unit;
an embedded multimedia card;
a memory device;
a wireless transceiver;
a power supply; or
an amplifier.

8. The electronic device of claim 1, wherein the at least one electronic component comprises electronic components of a wireless signal extender.

9. The electronic device of claim 1, further comprising a housing containing the at least one electronic component and the fan mechanism, wherein the housing has an overall size of less than five inches cubed.

10. The electronic device of claim 9, wherein the housing has an overall size of less than four inches cubed.

11. The electronic device of claim 1, wherein the controller is programmed to run the fan mechanism during the first predetermined time period at a speed of less than 2500 rpm.

12. The electronic device of claim 1, wherein the controller is programmed to run the fan mechanism during the first predetermined time period at a speed of about 2000 rpm or less.

13. An electronic device, comprising:
a central processing unit that generates heat during operation;
a wireless transceiver operably coupled to and controlled by the central processing unit;
a fan mechanism positioned and configured to induce flow of air to dissipate the heat generated by the central processing unit; and
a controller operably connected to the fan mechanism and programmed to intermittently operate the fan mechanism to repeatedly alternate between running the fan mechanism during a first predetermined time period and the fan mechanism being off during a second predetermined time period to maintain a temperature of the central processing unit at less than 80° C.

14. The electronic device of claim 13, wherein the intermittent operation of the fan mechanism maintains the temperature of the central processing unit at less than 75° C.

15. The electronic device of claim 13, wherein the controller is configured to operate the fan mechanism at a speed of less than 2500 rpm during the first predetermined time period.

16. The electronic device of claim 13, wherein the controller is configured to operate the fan mechanism to generate less than 12 decibels of sound when operating during the first predetermined time period.

17. The electronic device of claim 13, wherein the wireless transceiver is configured to receive a wireless signal and transmit an amplified wireless signal.

18. A method of forming an electronic device, the method comprising:
positioning a fan mechanism to induce flow of air to dissipate heat generated by an electronic component;
operably coupling a controller to the fan mechanism; and
programming the controller to intermittently operate the fan mechanism to repeatedly alternate between running the fan mechanism during a first predetermined time period and the fan mechanism being off during a second predetermined time period.

19. The method of claim 18, wherein the electronic device comprises a central processing unit and the intermittent operation of the fan mechanism maintains a temperature of the central processing unit at less than 80° C.

20. The method of claim 18, further comprising programming the controller to run the fan mechanism at less than 2500 rpm during the first predetermined time period.
